(19) United States
(12) Patent Application Publication
(10) Pub. No.: US 2025/0380583 A1
(43) Pub. Date: Dec. 11, 2025

(54) DISPLAY APPARATUS

(71) Applicant: Samsung Display Co., Ltd., Yongin-Si (KR)

(72) Inventors: Younggu Kang, Yongin-si (KR); Minji Kim, Yongin-si (KR); Hyeseok Na, Yongin-si (KR); Hyeondo Park, Yongin-si (KR); Hyunsung Park, Yongin-si (KR); Dongjin Seo, Yongin-si (KR)

(21) Appl. No.: 19/015,645

(22) Filed: Jan. 10, 2025

(30) Foreign Application Priority Data
Jun. 11, 2024 (KR) 10-2024-0075817

(51) Int. Cl. H10K 59/131; H10D 89/60; H10K 59/121

(52) U.S. Cl. CPC H10K 59/131; H10D 89/811; H10K 59/1216

(57) ABSTRACT

A display apparatus including a display area and a non-display area comprises a display unit disposed in a display area and including a light-emitting element and a pixel circuit, a common voltage supply line arranged in a non-display area surrounding the display area, a first conductive line arranged between the display unit and the common voltage supply line, a second conductive line arranged between the first conductive line and the common voltage supply line, an electrostatic discharge protective circuit having a first end connected to the first conductive line and a second end connected to the second conductive line and including a first protective transistor and a second protective transistor, and a signal transfer line including a contact portion in contact with the electrostatic discharge protective circuit.

### CROSS-REFERENCE TO RELATED APPLICATION

This application is based on and claims priority under 35 U.S.C. § 119 to Korean Patent Application No. 10-2024-0075817, filed on Jun. 11, 2024, in the Korean Intellectual Property Office, the disclosure of which is incorporated by reference herein in its entirety.

### BACKGROUND

### 1. Field

The present disclosure relates to a display apparatus in which a circuit damage due to electrostatic discharge is minimized.

### 2. Description of the Related Art

Recently, the usage of display apparatuses has diversified. In addition, as display apparatuses have become thinner and lighter, their range of use has gradually expanded.

As display apparatuses are utilized in various ways, there may be various methods of designing their shape, and furthermore, the functionalities that may be combined or associated with display apparatuses have been growing. Depending on their application, these display apparatuses may be implemented in various forms, such as those having either a standardized display area or a non-standardized display area.

However, conventional display apparatuses have had issues with reduced display quality due to a circuit damage caused by an electrostatic discharge.

### SUMMARY

The present disclosure includes a display apparatus in which a circuit damage due to the electrostatic discharge is minimized. However, such a technical feature is just an example, and the present disclosure is not limited thereto.

Additional aspects will be set forth in the description which follows and will be apparent from the description.

According to an embodiment, a display apparatus includes a display unit disposed in a display area and including a light-emitting element and a pixel circuit electrically connected to the light-emitting element, a common voltage supply line arranged in a non-display area surrounding the display area, a first conductive line arranged between the display unit and the common voltage supply line, a second conductive line arranged between the first conductive line and the common voltage supply line, an electrostatic discharge protective circuit having a first end connected to the first conductive line and a second end connected to the second conductive line, and including a first protective transistor arranged between the display unit and the first conductive line and a second protective transistor arranged between the first conductive line and the second conductive line, and a signal transfer line including a contact portion in contact with the electrostatic discharge protective circuit to transfer signals between the first protective transistor and the second protective transistor. The contact portion may be disposed between the display unit and the first conductive line.

The signal transfer line may be arranged between the display unit and the first conductive line.

The signal transfer line may be spaced apart from the second conductive line along a first direction.

The signal transfer line may be arranged closest to the display unit, and the common voltage line is arranged farthest to the display unit.

The electrostatic discharge protective circuit may have a bent portion between the first protective transistor and the second protective transistor.

The bent portion may be placed between the display unit and the first conductive line.

The contact portion of the signal transfer line may be connected to the bent portion.

The electrostatic discharge protective circuit may have a ‘V’ or ‘U’ shape.

A data signal may be applied to the signal transfer line.

The display unit may further include a data line extending in a first direction, and a first end of the signal transfer line may be electrically connected to the data line.

The electrostatic discharge protective circuit may include a doped active layer, and the doped active layer may overlap the first conductive line.

The display apparatus may further include a voltage transfer line electrically connecting the display unit to the common voltage supply line.

At least a portion of the voltage transfer line may overlap the first conductive line.

At least a portion of the voltage transfer line may overlap the second conductive line.

The signal transfer line and the voltage transfer line may be disposed on different layers from each other.

The signal transfer line may be disposed on a higher layer than the voltage transfer line.

The pixel circuit may include a semiconductor layer, a gate electrode overlapping at least a portion of the semiconductor layer, a storage electrode on the gate electrode, a first electrode layer on the storage electrode, and a second electrode layer on the first electrode layer. The signal transfer line may be disposed on a same layer as the storage electrode, and the voltage transfer line may be disposed on a same layer as the gate electrode.

At least a portion of the display area may include at least one rounded corner at an outer portion of the display unit.

At least a portion of the display area may include a polygonal shape.

The light-emitting element may be arranged in a diagonal or stepped shape in at least a portion of an outer portion of the display unit.

The display apparatus may be part of one of a mobile phone, a tablet, a mobile communication terminal, an electronic notebook, an e-book, a portable multimedia player, a navigation device, an ultra-mobile personal computer, a television, a monitor, a billboard, an Internet of Things device, a smart watch, a watch phone, glasses, a head mounted display, a vehicle dashboard, a vehicle mirror display, or a vehicle entertainment display.

Various features and aspects will become apparent and more readily appreciated from the following description of the embodiments, the accompanying drawings, and claims.

These general and specific aspects may be implemented using a system, a method, a computer program, or a combination of a certain system, method, or computer program.

### BRIEF DESCRIPTION OF THE DRAWINGS

The above and other aspects, features, and advantages of the present disclosure will be more apparent from the following description taken in conjunction with the accompanying drawings.

FIG. 1 is a schematic plan view of a display apparatus according to an embodiment.

FIG. 2 is a schematic plan view of a display apparatus according to an embodiment.

FIGS. 3 and 4 are schematic plan views of a display apparatus according to an embodiment.

FIGS. 5 to 7 are equivalent circuit diagrams of a pixel according to an embodiment.

FIG. 8 is a schematic cross-sectional view of a pixel according to an embodiment.

FIGS. 9A and 9B are circuit diagrams of an electrostatic discharge protective circuit of a display apparatus according to an embodiment.

FIG. 10 is a schematic plan view of a portion of a non-display area of a display apparatus according to an embodiment.

FIG. 11 is a schematic plan view of a portion of an electrostatic discharge preventing part of a display apparatus according to an embodiment, corresponding to a region A of FIG. 10.

FIG. 12 is a schematic cross-sectional view of a portion of an electrostatic discharge preventing part of a display apparatus, taken along a line B-B′ of FIG. 11.

FIG. 13 is a schematic cross-sectional view of a portion of an electrostatic discharge preventing part of a display apparatus, taken along a line C-C′ of FIG. 11.

FIG. 14 is a schematic cross-sectional view of a portion of an electrostatic discharge preventing part of a display apparatus, taken along a line D-D′ of FIG. 11.

FIG. 15 is a schematic cross-sectional view of a portion of an electrostatic discharge preventing part of a display apparatus, taken along a line E-E′ of FIG. 11.

FIG. 16 is a schematic cross-sectional view of a portion of an electrostatic discharge preventing part of a display apparatus, taken along a line F-F′ of FIG. 11.

### DETAILED DESCRIPTION

Hereinafter, embodiments of the present disclosure are explained in detail with reference to the accompanying drawings. Like numerals refer to like elements throughout. In this regard, embodiments of the present disclosure may have different forms and should not be construed as being limited to the descriptions set forth herein. Accordingly, the embodiments are merely described below, by referring to the drawings, to explain aspects of the present disclosure. As used herein, the word “or” means logical “or” so that, unless the context indicates otherwise, the expression “A, B, or C” means “A and B and C,” “A and B but not C,” “A and C but not B,” “B and C but not A,” “A but not B and not C,” “B but not A and not C,” and “C but not A and not B.”

As the present disclosure allows for various changes and can have numerous embodiments, specific embodiments will be illustrated in the drawings and described in the written description. The effects and features of the present disclosure, as well as the methods for achieving them will become clear with reference to embodiments described below in detail with reference to the drawings. However, it should be noted that the present disclosure is not limited to the following embodiments and may be implemented in various forms.

Hereinafter, embodiments will be described with reference to the accompanying drawings, wherein like reference numerals refer to like elements throughout and a repeated description thereof is omitted.

While the terms such as “first” and “second” may be used to describe various elements of the present disclosure, the elements must not be limited to the above terms. The above terms are used to distinguish one element from another.

The singular form, such as “a,” “an,” and “the” as used herein, is intended to include the plural forms as well unless the context clearly indicates otherwise.

It will be understood that the term, “comprise,” “comprising,” “include” or “including” as used herein, specifies the presence of stated features or elements but do not preclude the addition of one or more other features or elements.

It will be further understood that, when a layer, region, or element is referred to as being “on” another layer, region, or element, it can be directly or indirectly on the other layer, region, or element. That is, for example, intervening layers, regions, or elements may be present therebetween.

It will be understood that when a layer, region, or element is referred to as being “connected” to another layer, region, or element, it may be “directly connected” to another layer, region, or element or may be “indirectly connected” to another layer, region, or element with other layer, region, or element interposed therebetween. For example, it will be understood that when a layer, region, or element is referred to as being “electrically connected” to another layer, region, or element, it may be “directly electrically connected” to another layer, region, or element or may be “indirectly electrically connected” to another layer, region, or element with other layer, region, or element interposed therebetween.

The x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

In the case where a certain embodiment may be implemented differently, a specific process order may be performed in an order different from the described sequency. As an example, two processes successively described may be performed simultaneously or proceed in the reverse order to what is described.

Sizes of elements in the drawings may be exaggerated or reduced for convenience of explanation. As an example, the size and thickness of each element shown in the drawings are arbitrarily illustrated for convenience of description, and thus, the present disclosure is not necessarily limited thereto.

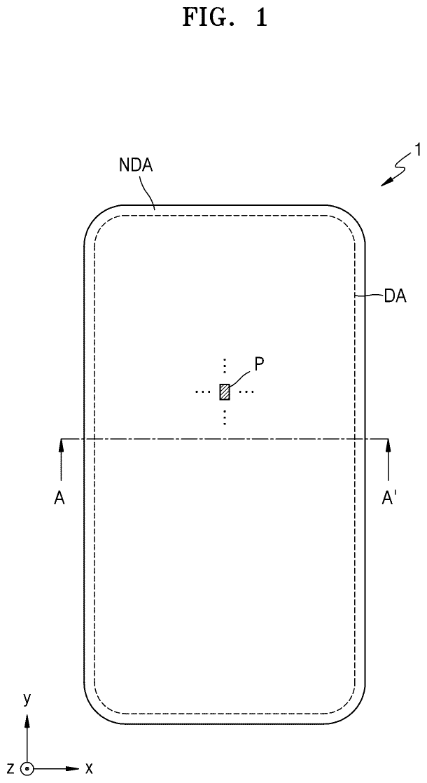

FIG. 1 is a schematic plan view of a display apparatus 1 according to an embodiment.

Referring to FIG. 1, the display apparatus 1 may include a display area DA and a non-display area NDA outside the display area DA. A plurality of pixels P each of which includes a display element may be arranged in the display area DA, and the display apparatus 1 may be configured to display images using light emitted from the plurality of pixels P arranged in the display area DA. The non-display area NDA is a region in which display elements are not arranged, and the display area DA may be entirely or partially surrounded by the non-display area NDA.

Although FIG. 1 shows the display apparatus 1 including a flat display surface, the present disclosure is not limited thereto. In an embodiment, the display apparatus 1 may include a three-dimensional display surface or a curved display surface.

When the display apparatus 1 includes a three-dimensional display surface, the display apparatus 1 may include a plurality of display areas indicating different directions from each other. For example, the display apparatus 1 may include a polygonal pillar-shaped display surface. In an embodiment, when the display apparatus 1 includes a curved display surface, the display apparatus 1 may be implemented in various shapes such as flexible, foldable, rollable display apparatuses, and the like.

The display apparatus 1 shown in FIG. 1 may be applicable to a mobile phone. Although not shown, electronic modules, a camera module, a power module, or the like mounted on a mainboard may be disposed in a bracket or a case of the mobile phone together with the display apparatus 1. In another example, the display apparatus 1 according to an embodiment may be applicable to large-sized electronic apparatuses such as televisions or monitors and small, or to medium-sized electronic apparatuses such as tablets, car navigation apparatuses, game consoles, or smartwatches.

Although FIG. 1 shows the case where the display area DA of the display apparatus 1 is a quadrangle with round edges, the shape of the display area DA may be a circular shape, an elliptical shape, or a polygonal shape such as a triangle or a pentagon.

Hereinafter, although an organic light-emitting display apparatus is described as an example of the display apparatus 1 according to an embodiment, the present disclosure is not limited thereto. For example, the display apparatus 1 according to an embodiment may be an inorganic light-emitting display apparatus or a quantum-dot light-emitting display apparatus. As an example, an emission layer of a display element provided to the display apparatus 1 may include an organic material, an inorganic material, quantum dots, an organic material and quantum dots, or an inorganic material and quantum dots.

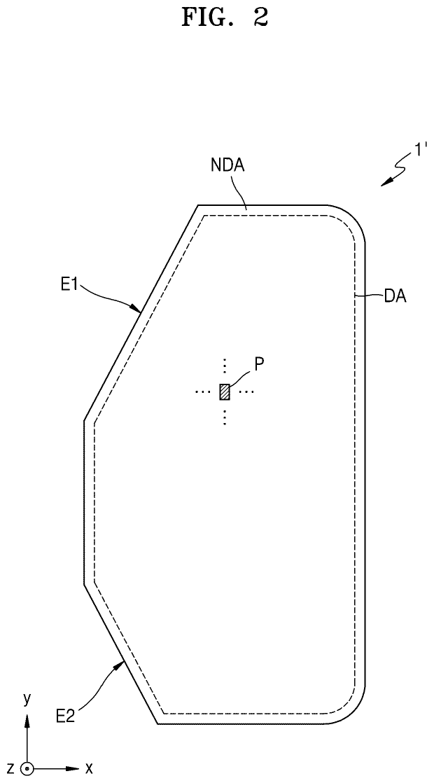

FIG. 2 is a schematic plan view of a display apparatus 1′ according to an embodiment.

Referring to FIG. 2, the display apparatus 1′ of FIG. 2 is different from the display apparatus 1 of FIG. 1 in the planar shape. That is, the display apparatus 1 of FIG. 1 includes the display area DA having a quadrangular shape with round corner portions, while the display apparatus 1′ of FIG. 2 may include the display area DA having an irregular shape.

The display apparatus 1′ may include the display area DA and the non-display area NDA surrounding the display area DA. At least a portion of the display area DA of the display apparatus 1′ may have a round shape in the outer portion. As an example, the display area DA of the display apparatus 1′ may have a corner portion in a round shape as in the display apparatus 1 of FIG. 1.

At least a portion of the display area DA of the display apparatus 1′ may have a polygonal shape, not a quadrangular shape. The interior angles of the polygonal shape may be greater than 90°, for example, the polygonal shape may have interior angles greater than 90° and less than 180°. It is shown in FIG. 2 that the upper and lower edges on the left side of the display area DA of the display apparatus 1′ have a diagonally cut shape so as to have a chamfered structure. When the upper chamfer structure of the display apparatus 1′ is referred to as a first inclined portion E1 and the lower chamfer structure of the display apparatus 1′ is referred to as a second inclined portion E2, the inclinations of the first inclined portion E1 and the second inclined portion E2 of the display apparatus 1′ may be symmetrical to each other or may be different from each other. It is shown in FIG. 2 that inclinations of the first inclined portion E1 and the second inclined portion E2 of the display apparatus 1′ are different from each other. In addition, the display apparatus 1′ may have a structure in which the length of the first inclined portion E1 is greater than the length of the second inclined portion E2. However, the present disclosure is not limited thereto and the display area DA may have various shapes.

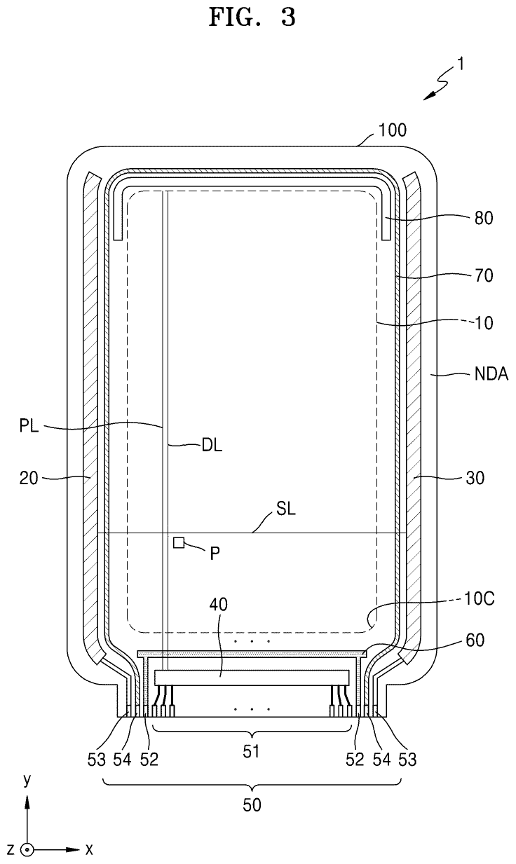

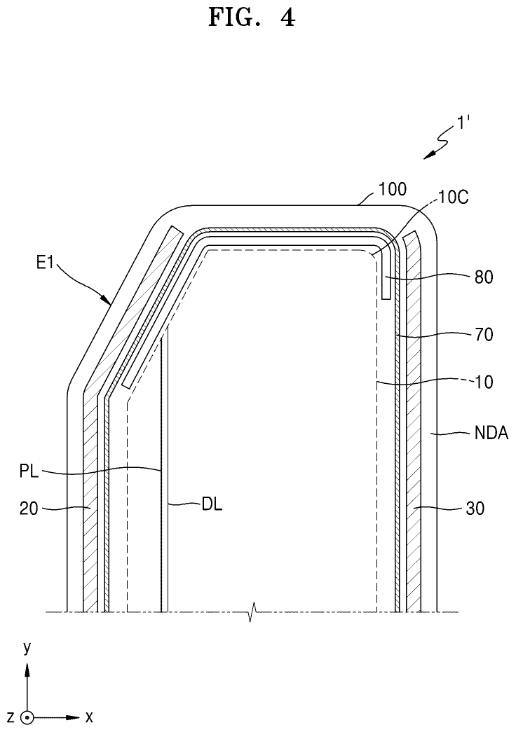

The display apparatus 1′ of FIG. 2 has the irregular display area DA as described above. The substrate 100 (see FIG. 4) in which various kinds of elements and wirings for implementing the display apparatus 1′ are disposed may be formed in an irregular shape similar to the shape of the display area DA of the display apparatus 1′. However, the shape of the substrate 100 according to an embodiment may not be necessarily formed along the shape of the display area DA. Even when the shape of the display area DA is formed irregularly, the substrate 100 may have a quadrangular shape or may have the shape similar to the substrate 100 (see FIG. 3) of the display apparatus 1 of FIG. 1.

FIGS. 3 and 4 are schematic plan views of the display apparatus 1 according to an embodiment.

The display apparatus 1 of FIG. 3 may correspond to the display apparatus 1 of FIG. 1, and the display apparatus 1′ of FIG. 4 may correspond to the display apparatus 1′ of FIG. 2.

Referring to FIG. 3, the display apparatus 1 includes a display unit 10, first and second scan drivers 20 and 30, a data driver 40, a terminal section 50, a driving voltage supply line 60, a common voltage supply line 70, and an electrostatic discharge preventing part 80.

The substrate 100 may include a material such as glass containing SiO₂ as a main component, metal, or an organic material. As another example, the substrate 100 may include a flexible material.

The display unit 10 may include the pixels P, each of which is connected to a scan line SL extending in a first direction, a data line DL extending in a second direction crossing the first direction, and a driving voltage line PL. Each pixel P may emit, for example, red, green, blue, or white light and may include, for example, an organic light-emitting diode. The display unit 10 may display preset images through light emitted from the pixels P, and the display area DA is defined by the pixels P. In the present disclosure, the non-display area NDA may be a region in which the pixels P are not arranged and may represent a region that does not display images.

The display unit 10 generally has a quadrangular shape, but may be provided in various forms such as a polygonal shape, a circular shape, or an irregular shape as depicted in FIG. 4. According to an embodiment, the display unit 10 has an overall quadrangular shape with rounded corner portions 10C at each edges. The substrate 100, on which the display unit 10 is placed, may have curved edges in at least a partial region of its outer perimeter.

The first and second scan drivers 20 and 30 may be arranged in the non-display area NDA of the substrate 100 and may generate and transfer scan signals to each pixel P through the scan line SL. According to an embodiment, the first scan driver 20 may be disposed on the left side of the display unit 10, and the second scan driver 30 may be disposed on the right side of the display unit 10.

The data driver 40 may be arranged in the non-display area NDA of the substrate 100 and may generate and transfer a data signal to each pixel P through the data line DL. The data driver 40 may be arranged on one side of the display unit 10, for example, arranged on a lower side of the display unit 10 where the terminal section 50 is arranged.

The terminal section 50 is placed on one end of the substrate 100 and includes a plurality of terminals 51, 52, 53, and 54. The terminal section 50 may not be covered by an insulating layer, and electrically connected to a controller (not shown) such as a flexible printed circuit board or an integrated circuit (IC) chip. The controller may convert a plurality of image signals received from the outside to a plurality of image data signals, and transmit the converted signals to the data driver 40 through the terminal 51. In addition, the controller may receive a vertical synchronization signal, a horizontal synchronization signal, and a clock signal, generate control signals for controlling the first and second scan drivers 20 and 30, and the data driver 40, and transmit the control signals to each of the first and second scan drivers 20 and 30, and the data driver 40 through the terminals 51 and 53. The controller may further transmit a driving voltage ELVDD and a common voltage ELVSS to the driving voltage supply line 60 and the common voltage supply line 70, respectively, through the terminals 52 and 54.

The driving voltage supply line 60 may be arranged in the non-display area NDA. For example, the driving voltage supply line 60 may be arranged between the data driver 40 and the display unit 10. The driving voltage supply line 60 may provide the driving voltage ELVDD to the pixels P. The driving voltage supply line 60 may be arranged along the first direction and connected to a plurality of first driving voltage lines PL1 extending in the second direction.

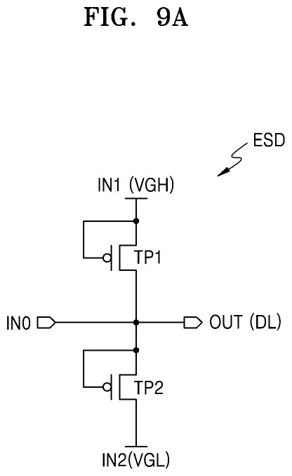

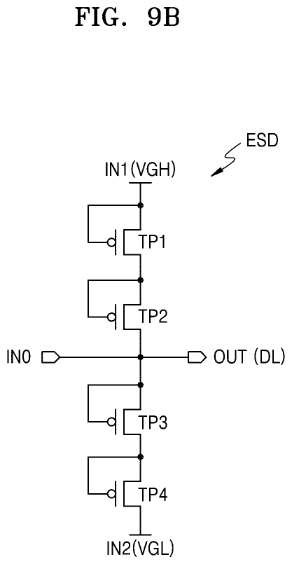

The common voltage supply line 70 is arranged in the non-display area NDA and provides the common voltage ELVSS to an opposite electrode 233 (see FIG. 9) of an organic light-emitting diode of the pixel P. For example, the common voltage supply line 70 has a closed-loop shape except one open side and may extend along the edges of the substrate 100 except for the terminal section 50.

The display unit 10 has a quadrangular shape in overall and includes the rounded corner portion 10C. The rounded corner portion 10C may be placed in each of four edges of the display unit 10 and be a part of a circle with a preset curvature.

The display apparatus 1 may include the electrostatic discharge preventing part 80. The electrostatic discharge preventing part 80 may be arranged in the non-display area NDA. As shown in FIG. 3, the electrostatic discharge preventing part 80 may be arranged on the upper end of the display area DA. It may be understood that electrostatic discharge frequently occurs in this area, i.e., the upper end of the display area DA. As an example, in a plan view, the electrostatic discharge preventing part 80 may be arranged on the upper end of the display area DA and may partially extend in a -y direction toward the terminal section 50.

The electrostatic discharge preventing part 80 may include an electrostatic discharge protective circuit ESD for protecting an inner circuit from a damage caused by a high-voltage pulse. The electrostatic discharge protective circuit ESD may prevent static charges from flowing into the inner circuits and discharge the static charges to ground.

The display apparatus 1′ of FIG. 4 is a different planar shape than the display apparatus 1 of FIG. 3. That is, the display apparatus 1 of FIG. 4 may include the display area DA having an irregular shape. According to an embodiment depicted in FIG. 4, the substrate 100 may include an irregular shape similar to the display area DA of the display apparatus 1′. FIG. 4 mainly shows the upper end of the display apparatus 1′, and a lower portion (not shown) may be identical or similar to the configuration as depicted in FIG. 3.

FIG. 4 illustrates that the upper left side of the display area DA of the display apparatus 1′ has a diagonally cut shape so as to have a chamfered structure. As an example, the first inclined portion E1 may be provided to the upper left side of the display apparatus 1′, and the rounded corner portion 10C may be provided to the upper right side. As the upper left side of the display apparatus 1′ includes the first inclined portion E1 as described above, the arrangement of elements located in the upper left side may be different from that of the display apparatus 1 of FIG. 3.

In the display apparatus 1′ of FIG. 4, the electrostatic discharge preventing part 80 may be arranged along the outer perimeter of the display area DA. According to an embodiment, the electrostatic discharge preventing part 80 may be placed on the upper end of the display area DA and extend along an x axis direction. At the rounded corner portion 10C, the electrostatic discharge preventing part 80 may extend along the -y direction. In addition, the electrostatic discharge preventing part 80 may partially extend diagonally to correspond to the first inclined portion E1, resulting in an asymmetric ‘U’ shape. In the display apparatus 1′, since a circuit damage due to external electrostatic discharge frequently occurs on the upper end of the display area DA, the electrostatic discharge preventing part 80 may be arranged in the structure, as described above.

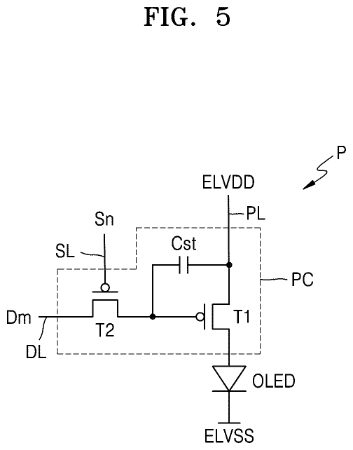

FIGS. 5 to 7 are equivalent circuit diagrams of the pixel P according to an embodiment.

Referring to FIG. 5, each pixel P may include a pixel circuit PC and a light-emitting element. According to an embodiment, the light emitting element may be an organic light-emitting diode OLED which is connected to the pixel circuit PC, and the pixel circuit PC is connected to the scan line SL and the data line DL.

The pixel circuit PC includes a driving thin-film transistor T1, a switching thin-film transistor T2, and a storage capacitor Cst. The switching thin-film transistor T2 is connected to the scan line SL and the data line DL, and transmits a data signal Dm to the driving thin-film transistor T1 in response to a scan signal Sn. The data signal Dm may be input through the data line DL, and the scan signal Sn may be input through the scan line SL.

The storage capacitor Cst may be connected to the switching thin-film transistor T2 and the driving voltage line PL and may store a voltage corresponding to a difference between a voltage transferred from the switching thin-film transistor T2 and the driving voltage ELVDD provided through the driving voltage line PL.

The driving thin-film transistor T1 may be connected to the driving voltage line PL and the storage capacitor Cst and may control a driving current in response to the voltage stored in the storage capacitor Cst. The driving current may flow from the driving voltage line PL to the organic light-emitting diode OLED. The organic light-emitting diode OLED may emit light having a preset brightness corresponding to the driving current.

Although the pixel circuit PC in FIG. 5 includes two thin-film transistors and one storage capacitor, the present disclosure is not limited thereto.

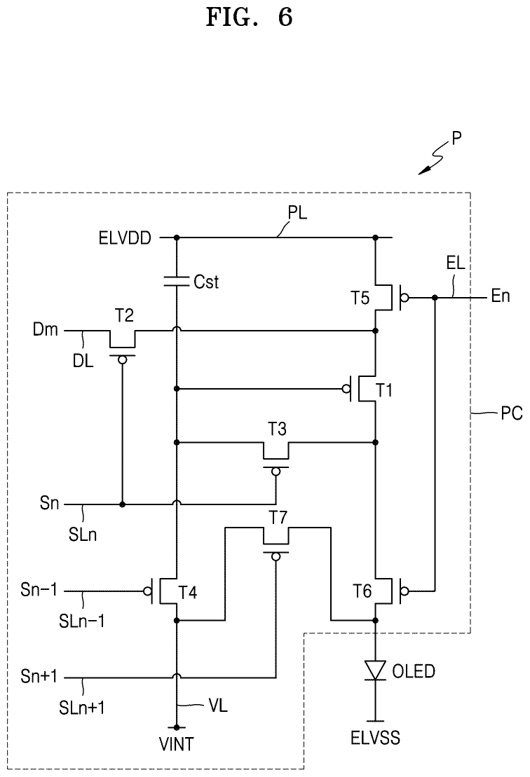

Referring to FIG. 6, the pixel circuit PC may include not only the driving and switching thin-film transistors T1 and T2 but also further include a compensation thin-film transistor T3, a first initialization thin-film transistor T4, a first emission control thin-film transistor T5, a second emission control thin-film transistor T6, and a second initialization thin-film transistor T7.

A drain electrode of the driving thin-film transistor T1 may be electrically connected to the organic light-emitting diode OLED via the emission control thin-film transistor T6. The driving thin-film transistor T1 may receive a data signal Dm and supply the driving current to the organic light-emitting diode OLED in response to a switching operation of the switching thin-film transistor T2.

A gate electrode of the switching thin-film transistor T2 is connected to a first scan line SL, and a source electrode is connected to the data line DL. A drain electrode of the switching thin-film transistor T2 may be connected to the source electrode of the driving thin-film transistor T1, and connected to the driving voltage line PL via the first emission control thin-film transistor T5.

The switching thin-film transistor T2 is turned on in response to a first scan signal Sn transferred through the first scan line SL and performs a switching operation to trasmit a data signal Dm from the data line DL to a source electrode of the driving thin-film transistor T1.

A gate electrode of the compensation thin-film transistor T3 may be connected to the first scan line SL. A source electrode of the compensation thin-film transistor T3 is connected to a drain electrode of the driving thin-film transistor T1 and connected to a pixel electrode of the organic light-emitting diode OLED via the second emission control thin-film transistor T6. A drain electrode of the compensation thin-film transistor T3 may be connected to a first electrode of the storage capacitor Cst, a source electrode of the first initialization thin-film transistor T4, and the gate electrode of the driving thin-film transistor T1. The compensation thin-film transistor T3 is turned on in response to a first scan signal Sn received through the first scan line SL and diode-connect the driving thin-film transistor T1 by connecting the gate electrode and the drain electrode of the driving thin-film transistor T1 to each other.

A gate electrode of the first initialization thin-film transistor T4 may be connected to a second scan line SLn−1. A drain electrode of the first initialization thin-film transistor T4 may be connected to an initialization voltage line VL. A source electrode of the first initialization thin-film transistor T4 may be connected to the first electrode of the storage capacitor Cst, a drain electrode of the compensation thin-film transistor T3, and the gate electrode of the driving thin-film transistor T1. The first initialization thin-film transistor T4 may be turned on in response to a second scan signal Sn−1 received through the second scan line SLn−1 and may perform an initialization operation which initializes the voltage of the gate electrode of the driving thin-film transistor T1 by transferring an initialization voltage VINT to the gate electrode of the driving thin-film transistor T1.

A gate electrode of the first emission control thin-film transistor T5 may be connected to an emission control line EL. A source electrode of the first emission control thin-film transistor T5 may be connected to the driving voltage line PL. A drain electrode of the first emission control thin-film transistor T5 is connected to the source electrode of the driving thin-film transistor T1 and the drain electrode of the switching thin-film transistor T2.

A gate electrode of the second emission control thin-film transistor T6 may be connected to the emission control line EL. A source electrode of the second emission control thin-film transistor T6 may be connected to the drain electrode of the driving thin-film transistor T1 and the source electrode of the compensation thin-film transistor T3. A drain electrode of the second emission control thin-film transistor T6 may be electrically connected to the pixel electrode of the organic light-emitting diode OLED. The first emission control thin-film transistor T5 and the second emission control thin-film transistor T6 may be simultaneously turned on in response to an emission control signal En transferred through the emission control line EL, and the driving current flows through the organic light-emitting diode OLED.

A gate electrode of the second initialization thin-film transistor T7 may be connected to a third scan line SLn+1. A source electrode of the second initialization thin-film transistor T7 may be connected to the pixel electrode of the organic light-emitting diode OLED. A drain electrode of the second initialization thin-film transistor T7 may be connected to the initialization voltage line VL. The second initialization thin-film transistor T7 may be turned on in response to a third scan signal Sn+1 transferred through the third scan line SLn+1 to initialize the pixel electrode of the organic light-emitting diode OLED.

A second electrode of the storage capacitor Cst may be connected to the driving voltage line PL. The first electrode of the storage capacitor Cst may be connected to the gate electrode of the driving thin-film transistor T1, the drain electrode of the compensation thin-film transistor T3, and the source electrode of the first initialization thin-film transistor T4.

An opposite electrode of the organic light-emitting diode OLED is connected to the common voltage ELVSS. The organic light-emitting diode OLED emits light in response to the driving current from the driving thin-film transistor T1.

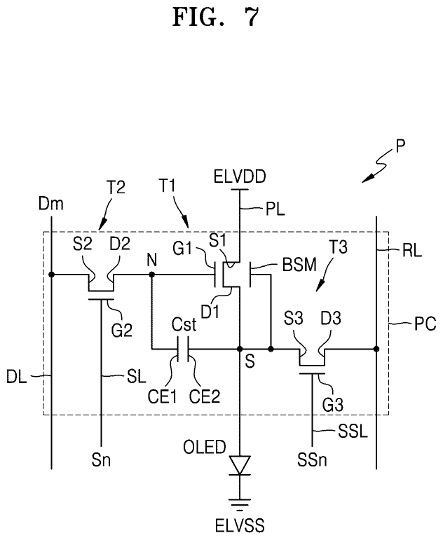

Referring to FIG. 7, the pixel circuit PC may include the driving thin-film transistor T1, the switching thin-film transistor T2, a sensing thin-film transistor T3, and the storage capacitor Cst.

The switching thin-film transistor T2 may include a gate electrode G2 connected to the scan line SL, a source electrode S2 connected to the data line DL, and a drain electrode connected to a first electrode CE1 of the storage capacitor Cst.

Accordingly, the switching thin-film transistor T2 may supply a data voltage of the data line DL to a first node N in response to a scan signal Sn from the scan line SL.

The driving thin-film transistor T1 may include a gate electrode G1 connected to the first node N, a source electrode S1 connected to the driving voltage line PL, which transmits the driving voltage ELVDD, and a drain electrode D1 connected to an anode electrode of the organic light-emitting diode OLED.

Accordingly, the driving thin-film transistor T1 may adjust the amount of a driving current flowing through the organic light-emitting diode OLED in response to a source-gate voltage Vgs of the driving thin-film transistor T1, that is, a voltage applied between the driving voltage ELVDD and the first node N.

The sensing thin-film transistor T3 may include a gate electrode G3 connected to a sensing control line SSL, a source electrode S3 connected to a second node S, and a drain electrode D3 connected to a reference voltage line RL. The gate electrode G3 of the sensing thin-film transistor T3 may be connected to the scan line SL instead of the sensing control line SSL.

The sensing thin-film transistor T3 may sense an electrical potential of a first electrode (e.g., an anode) of the organic light-emitting diode OLED. The sensing thin-film transistor T3 may supply a pre-charging voltage from the reference voltage line RL to the second node S in response to a sensing signal SSn from the sensing control line SSL, or supply a voltage of the first electrode (e.g., the anode) of the organic light-emitting diode OLED to the reference voltage line RL during a sensing period.

The storage capacitor Cst may include the first electrode CE1 connected to the first node N, and a second electrode CE2 connected to the second node S. The storage capacitor Cst may be charged with a difference voltage between voltages respectively supplied to the first and second nodes N and S, and may supply the difference voltage as a driving voltage of the driving thin-film transistor T1. For example, the storage capacitor Cst may be charged with a difference voltage between a data voltage Dm and a pre-charging voltage Vpre supplied to the first and second nodes N and S, respectively.

The driving thin-film transistor T1 may include a bias electrode BSM connected to the source electrode S3 of the sensing thin-film transistor T3. As the bias electrode BSM receives a voltage from the source electrode S3 of the sensing thin-film transistor T3, the driving thin-film transistor T1 may be stabilized. According to an embodiment, the bias electrode BSM may not be connected to the source electrode S3 of the sensing thin-film transistor T3 but may be connected to a separate bias line.

A second electrode (e.g., a cathode) of the organic light-emitting diode OLED may receive the common voltage ELVSS. The organic light-emitting diode OLED may emit light by receiving the driving current from the driving thin-film transistor T1.

Although FIG. 7 illustrates that the signal lines, such as the scan line SL, the sensing control line SSL, the data line DL, the reference voltage line RL, and the driving voltage line PL, are provided for each pixel, the present disclosure is not limited thereto. For example, at least one of the signals lines, e.g., at least one of the scan line SL, the sensing control line SSL, the data line DL, the reference voltage line RL or the driving voltage line PL, may be shared by adjacent pixels.

The pixel circuit PC is not limited to the number and circuit design of thin-film transistors and the storage capacitors described with reference to FIGS. 5 to 7. The number and the circuit design of thin-film transistors and the storage capacitors may be modified in various ways.

The pixel circuit PC described with reference to FIGS. 5 to 7 may be individually included in the different display apparatuses 1 and 1′ or included in the same display apparatuses 1 and 1′, simultaneously. That is, the display apparatuses 1 and 1′ according to an embodiment may include the pixel circuit PC of FIG. 5, may include the pixel circuit PC of FIG. 6, or may include the pixel circuit PC of FIG. 7. However, the present disclosure is not limited thereto. The display apparatuses 1 and 1′ according to an embodiment may include at least two kinds of pixel circuits PC at the same time among the pixel circuits PC shown in FIGS. 5 to 7.

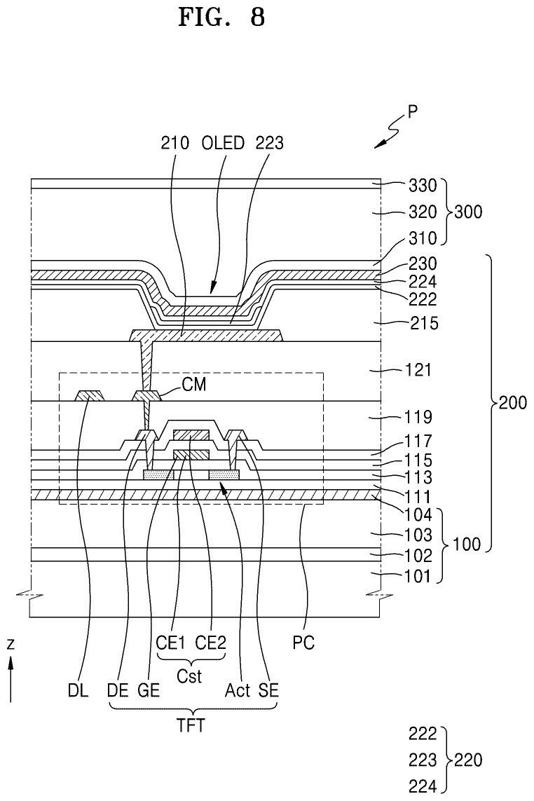

FIG. 8 is a schematic cross-sectional view of the pixel P according to an embodiment.

Referring to FIG. 8, the pixel P is arranged on the substrate 100. The pixel P may include the light-emitting element (referred to as the organic light-emitting diode OLED) and the pixel circuit PC which is connected to the organic light-emitting diode OLED and controls the emission of light from the organic light-emitting diode OLED. In the following description, As the pixel circuit PC included in each pixel P has the same configuration, the structure of the pixel circuit PC will be explained mainly focusing on a single pixel.

The substrate 100 may include glass or polymer resin. For example, the polymer resin forming the substrate 100 may include polyethersulfone, polyacrylate, polyetherimide, polyethylene naphthalate, polyethylene terephthalate, polyphenylene sulfide, polyarylate, polyimide, polycarbonate, or cellulose acetate propionate.

According to an embodiment, the substrate 100 may include a plurality of sub-layers. The plurality of sub-layers may have a structure in which organic layers and inorganic layers are alternately stacked. In this case, the substrate 100 may include a first sub-substrate 101, a first barrier layer 102, a second sub-substrate 103, and a second barrier layer 104. The first sub-substrate 101 and the second sub-substrate 103 may include polymer resin including polyethersulfone, polyarylate, polyetherimide, polyethylene naphthalate, polyethylene terephthalate, polyphenylene sulfide, polyimide, polycarbonate, cellulose tri acetate, or cellulose acetate propionate. Each of the first barrier layer 102 and the second barrier layer 104 may include an inorganic insulating material such as silicon oxide, silicon nitride, or silicon oxynitride.

A display layer 200 including a display element such as the organic light-emitting diode, and a thin-film encapsulation layer 300 covering the display layer 200 may be disposed on the substrate 100. Hereinafter, the display layer 200 will be described in detail below.

A buffer layer 111 may be formed on the substrate 100. The buffer layer 111 may prevent impurities from penetrating into a semiconductor layer Act of a thin-film transistor TFT. The buffer layer 111 may include an inorganic insulating material such as silicon nitride, silicon oxynitride or silicon oxide, and may be a single layer or a multilayer including the above inorganic insulating materials.

The pixel circuit PC may be disposed on the buffer layer 111. The pixel circuit PC may be disposed in each pixel P.

The pixel circuit PC includes the thin-film transistor TFT and a storage capacitor Cst. The thin-film transistor TFT may include the semiconductor layer Act, a gate electrode GE, a source electrode SE, and a drain electrode DE.

Although not shown in FIG. 8, the data line DL of the pixel circuit PC may be electrically connected to the switching thin-film transistor included in the pixel circuit PC. Although FIG. 8 shows a top-gate type thin-film transistor in which the gate electrode GE is disposed on the semiconductor layer Act with a gate insulating layer 113 therebetween, the thin-film transistor TFT may be a bottom-gate type thin-film transistor.

The semiconductor layer Act may include an oxide semiconductor. In another example, the semiconductor layer Act may include amorphous silicon, polycrystalline silicon, an organic semiconductor, or the like.

The gate electrode GE may include a low-resistance metal material. The gate electrode GE may include a conductive material including molybdenum (Mo), aluminum (Al), copper (Cu) or titanium (Ti), and may have a single-layered structure or a multi-layered structure including the above materials.

The gate insulating layer 113 between the semiconductor layer Act and the gate electrode GE may include an inorganic insulating material, such as silicon oxide, silicon nitride, silicon oxynitride, aluminum oxide, titanium oxide, tantalum oxide, hafnium oxide or the like. The gate insulating layer 113 may be a single layer or a multi-layer including the above materials.

Each of the source electrode SE and the drain electrode DE may include a material having high conductivity. Each of the source electrode SE and the drain electrode DE may include a conductive material such as molybdenum (Mo), aluminum (Al), copper (Cu) or titanium (Ti), and may be a single layer or a multi-layer including the above materials. For example, the source electrode SE and the drain electrode DE may include a multi-layered Ti/Al/Ti.

The storage capacitor Cst may include a first electrode CE1 and a second electrode CE2 overlapping each other with a first interlayer insulating layer 115 therebetween. The storage capacitor Cst may overlap the thin-film transistor TFT. According to an embodiment, the gate electrode GE of the thin-film transistor TFT may serve as the first electrode CE1 of the storage capacitor Cst. In another example, the storage capacitor Cst may not overlap the thin-film transistor TFT. The storage capacitor Cst may be covered by a second interlayer insulating layer 117. The second electrode CE2 of the storage capacitor Cst may include a conductive material including molybdenum (Mo), aluminum (Al), copper (Cu) or titanium (Ti), and may have a single-layered structure or a multi-layered structure including the above materials.

Each of the first interlayer insulating layer 115 and the second interlayer insulating layer 117 may include an inorganic insulating material such as silicon oxide, silicon nitride, silicon oxynitride, aluminum oxide, titanium oxide, tantalum oxide, hafnium oxide or the like. The first interlayer insulating layer 115 and the second interlayer insulating layer 117 may be a single layer or a multi-layer including the above materials.

The pixel circuit PC including the thin-film transistor TFT and the storage capacitor Cst may be covered by a first planarization insulating layer 119. The first planarization insulating layer 119 may form an approximately flat upper surface.

Although not shown, a third interlayer insulating layer (not shown) may be further disposed between the first planarization insulating layer 119 and the second interlayer insulating layer 117 to cover the source electrode SE and the drain electrode DE. The third interlayer insulating layer may include an inorganic insulating material such as silicon oxide, silicon nitride, or silicon oxynitride.

The pixel circuit PC may be electrically connected to a first electrode 210. As an example, as shown in FIG. 8, a contact metal layer CM may be disposed between the thin-film transistor TFT and the first electrode 210. The contact metal layer CM may be connected to the thin-film transistor TFT through a contact hole extending through the first planarization insulating layer 119, and the first electrode 210 may be connected to the contact metal layer CM through a contact hole extending through a second planarization insulating layer 121. The contact metal layer CM may include a conductive material including molybdenum (Mo), aluminum (Al), copper (Cu) or titanium (Ti), and may have a single-layered structure or a multi-layered structure including the above materials. In an embodiment, the contact metal layer CM may include a multi-layered Ti/Al/Ti.

The data line DL may be disposed on the same layer as the contact metal layer CM and may include the same material as the contact metal layer CM. In an embodiment, the data line DL may include a multi-layered Ti/Al/Ti. Although not shown, the data line DL may be electrically connected to the switching transistor through a lower contact metal (not shown) disposed on the same layer as the source electrode SE and the drain electrode DE.

The first planarization insulating layer 119 and the second planarization insulating layer 121 may include an organic insulating material such as polymethylmethacrylate (PMMA), polystyrene (PS), polymer derivatives having a phenol-based group, an acryl-based polymer, an imide-based polymer, an aryl ether-based polymer, an amide-based polymer, a fluorine-based polymer, a p-xylene-based polymer, a vinyl alcohol-based polymer, or a combination thereof. In an embodiment, each of the first planarization insulating layer 119 and the second planarization insulating layer 121 may include polyimide.

The organic light-emitting diode OLED may be disposed on the second planarization insulating layer 121. The organic light-emitting diode OLED may include the first electrode 210, a first common layer 222, an emission layer 223, a second common layer 224, and a second electrode 230. In the organic light-emitting diode OLED, the first electrode 210 and the emission layer 223 are patterned to be disposed in each pixel, and the first common layer 222, the second common layer 224, or the second electrode 230 are commonly provided in the display area DA. That is, at least one of the first common layer 222, the second common layer 224 or the second electrode 230 is disposed on a plurality of pixels in the display area DA.

The first electrode 210 may include a conductive oxide such as indium tin oxide (ITO), indium zinc oxide (IZO), zinc oxide (ZnO), indium oxide (In₂O₃), indium gallium oxide (IGO), or aluminum zinc oxide (AZO). In an embodiment, the first electrode 210 may include a reflective layer including silver (Ag), magnesium (Mg), aluminum (AI), platinum (Pt), palladium (Pd), gold (Au), nickel (Ni), neodymium (Nd), iridium (Ir), chrome (Cr), or a compound thereof. In an embodiment, the first electrode 210 may further include a layer on or under the reflective layer, and the layer may include ITO, IZO, ZnO, or In₂O₃. For example, the first electrode 210 may have a multi-layered ITO/Ag/ITO.

A pixel-defining layer 215 may be formed on the first electrode 210. The pixel-defining layer 215 may include an opening that extends to the upper surface of the first electrode 210, and cover the edges of the first electrode 210. The pixel-defining layer 215 may include an organic insulating material. In another example, the pixel-defining layer 215 may include an inorganic insulating material such as silicon nitride, silicon oxynitride, or silicon oxide. In another example, the pixel-defining layer 215 may include an organic insulating material and an inorganic insulating material.

An intermediate layer 220 may include the first common layer 222, the emission layer 223 or the second common layer 224. The emission layer 223 may include a polymer organic material or a low-molecular weight organic material emitting light having a preset color. The emission layer 223 may emit one of red light, blue light, or green light.

In addition, the intermediate layer 220 may include the first common layer 222 disposed between the emission layer 223 and the first electrode 210, or the second common layer 224 disposed between the emission layer 223 and the second electrode 230.

The first common layer 222 may be a single layer or a multi-layer. For example, when the first common layer 222 is formed of a polymer material, the first common layer 222 may serve as a hole transport layer (HTL), which has a single-layered structure, and may include polyethylene dihydroxythiophene (PEDOT: poly-(3,4)-ethylene-dihydroxy thiophene) or polyaniline (PANI: polyaniline). When the first common layer 222 is formed of a low-molecular weight material, the first common layer 222 may include a hole injection layer (HIL) and an HTL.

The second common layer 224 may be omitted. When the first common layer 222 and the emission layer 223 include a polymer material, the second common layer 2224 may be formed. The second common layer 224 may be a single layer or a multi-layer. The second common layer 224 may include an electron transport layer (ETL) or an electron injection layer (EIL).

The second electrode 230 may include a conductive material having a low work function. For example, the second electrode 230 may include a (semi) transparent layer including silver (Ag), magnesium (Mg), aluminum (Al), platinum (Pt), palladium (Pd), gold (Au), nickel (Ni), neodymium (Nd), iridium (Ir), chrome (Cr), or an alloy thereof. The second electrode 230 may further include a layer on a (semi) transparent layer, and the layer may include ITO, IZO, ZnO, or In₂O₃.

A capping layer (not shown) may be disposed on the second electrode 230. For example, the capping layer may have a single layered or a multi-layered structure including an organic material, an inorganic material, or a mixture thereof. Depending on the case, a LiF layer may be disposed on the capping layer.

Because the organic light-emitting diode OLED may be easily damaged by external moisture, oxygen, or the like, the organic light-emitting diode OLED may be protected by being covered by a thin-film encapsulation layer 300. The thin-film encapsulation layer 300 may cover the display area DA and extend to the non-display area outside the display area DA. The thin-film encapsulation layer 300 includes at least one organic encapsulation layer and at least one inorganic encapsulation layer. As an example, the thin-film encapsulation layer 300 includes a first inorganic encapsulation layer 310, an organic encapsulation layer 320, and a second inorganic encapsulation layer 330.

The first inorganic encapsulation layer 310 may cover the second electrode 230 and include silicon oxide, silicon nitride, or silicon oxynitride. Because the first inorganic encapsulation layer 310 is formed along a structure thereunder, an upper surface of the first inorganic encapsulation layer 310 may not be flat. The organic encapsulation layer 320 may cover the first inorganic encapsulation layer 310 and may have a flat upper surface. Specifically, the upper surface of a portion of the organic encapsulation layer 320 that corresponds to the display area DA may be approximately flat. The organic encapsulation layer 320 may include, for example, at least one of polyethylene terephthalate, polyethylene naphthalate, polycarbonate, polyimide, polyethylene sulfonate, polyoxymethylene, polyarylate, hexamethyldisiloxane, or acryl-based resin (e.g., polymethylmethacrylate, poly acrylic acid, and the like). The second inorganic encapsulation layer 330 may cover the organic encapsulation layer 320 and include silicon oxide, silicon nitride, or silicon oxynitride.

Even when cracks occur inside the thin-film encapsulation layer 300, the thin-film encapsulation layer 300 may prevent the cracks from being connected between the first inorganic encapsulation layer 310 and the organic encapsulation layer 320 or between the organic encapsulation layer 320 and the second inorganic encapsulation layer 330 due to the above multi-layered structure. With this configuration, forming a path through which external moisture or oxygen penetrates into the display area DA may be prevented or minimized.

FIGS. 9A and 9B are circuit diagrams of an electrostatic discharge protective circuit of a display apparatus according to an embodiment.

The electrostatic discharge preventing part 80 according to an embodiment may include at least one electrostatic discharge protective circuit ESD. The electrostatic discharge protective circuit ESD may discharge static electricity introduced from the outside and protect an inner circuit, that is, the pixel circuit PC (see FIG. 8 and the like), from static electricity.

Referring to FIG. 9A, the electrostatic discharge protective circuit ESD may include an input terminal INO, a first power input terminal IN1, a second power input terminal IN2, and an output terminal OUT. The first power input terminal IN1 may be connected to a gate-high voltage line VGH, and the second power input terminal IN2 may be connected to a gate-low voltage line VGL. In addition, the output terminal OUT of the electrostatic discharge protective circuit ESD may be electrically connected to the data line DL to discharge static electricity introduced through the data line DL.

The electrostatic discharge protective circuit ESD may include a first protective transistor TP1 and a second protective transistor TP2. Each of the first protective transistor TP1 and the second protective transistor TP2 may include a gate electrode, a first electrode, and a second electrode. According to an embodiment, the gate electrodes of each of the first and second protective transistors TP1 and TP2 may be connected to the first electrodes of each of the first protective transistor TP1 and the second protective transistor TP2, respectively. Accordingly, each of the first and second protective transistors TP1 and TP2 may be a transistor that is diode-connected in a reverse direction.

The first electrode of the first protective transistor TP1 may be connected to the gate-high voltage line VGH, and the second electrode of the first protective transistor TP1 may be electrically connected to the data line DL. When a voltage higher than the first power voltage (that is, the driving voltage ELVDD) of the gate-high voltage line VGH is applied to the data line DL due to electrostatic discharge, the first protective transistor TP1 may be turned on. In this case, a current (e.g., a current due to electrostatic discharge) may flow from the data line DL to the gate-high voltage line VGH, and a voltage on the data line DL may be reduced. That is, the first protective transistor TP1 may drop a voltage that is higher than the first power voltage.

A first electrode of the second protective transistor TP2 may be electrically connected to the data line DL, and a second electrode of the second protective transistor TP2 may be electrically connected to the gate-low voltage line VGL. When a voltage less than the second power voltage (that is, the common voltage ELVSS) of the gate-low voltage line VGL is applied to the data line DL due to electrostatic discharge, the second protective transistor TP2 may be turned on. In this case, a current may flow from the low voltage line VGL to the data line DL, and a voltage on the data line DL may increase. That is, the second protective transistor TP2 may increase a voltage that is less than the second power voltage.

A voltage on the data line DL may be maintained between the first power voltage and the second power voltage by the first and second protective transistors TP1 and TP2, allowing an inner circuit to be protected from electrostatic discharge.

While FIG. 9A describes the case where the electrostatic discharge protective circuit ESD includes two protective transistors, the electrostatic discharge protective circuit ESD according to an embodiment may include four or more protective transistors as shown in FIG. 9B. In FIG. 9B and the following figures, the electrostatic discharge protective circuit ESD is illustrated as having a structure based on the circuit diagram shown in FIG. 9B.

Referring to FIG. 9B, the electrostatic discharge protective circuit ESD may include the input terminal INO, the first power input terminal IN1, the second power input terminal IN2, and the output terminal OUT. The first power input terminal IN1 may be connected to the gate-high voltage line VGH, and the second power input terminal IN2 may be connected to the gate-low voltage line VGL. In addition, the output terminal OUT of the electrostatic discharge protective circuit ESD may be electrically connected to the data line DL to discharge static electricity introduced through the data line DL.

The electrostatic discharge protective circuit ESD may include the first protective transistor TP1, the second protective transistor TP2, a third protective transistor TP3, and a fourth protective transistor TP4. Each of the first protective transistor TP1, the second protective transistor TP2, the third protective transistor TP3, and the fourth protective transistor TP4 may include a gate electrode, a first electrode, and a second electrode. In this case, the gate electrodes of each of the first to fourth protective transistors TP1, TP2, TP3, and TP4 may be connected to the first electrodes of each of the first protective transistor TP1, the second protective transistor TP2, the third protective transistor TP3 and the fourth protective transistor TP4, respectively. Accordingly, each of the first to fourth protective transistors TP1, TP2, TP3, and TP4 may include a transistor that is diode-connected in a reverse direction.

The first electrode of the first protective transistor TP1 may be connected to the gate-high voltage line VGH, and the second electrode of the second protective transistor TP2 may be electrically connected to the data line DL. When a voltage higher than the first power voltage (that is, the driving voltage ELVDD) of the gate-high voltage line VGH is applied to the data line DL due to electrostatic discharge, the first protective transistor TP1 and the second protective transistor TP2 may be turned on. In this case, a current (e.g., a current due to electrostatic discharge) may flow from the data line DL to the gate-high voltage line VGH, and a voltage on the data line DL may be reduced. That is, the first protective transistor TP1 and the second protective transistor TP2 may drop a voltage that is higher than the first power voltage.

A first electrode of the third protective transistor TP3 may be electrically connected to the data line DL, and a second electrode of the fourth protective transistor TP4 may be electrically connected to the gate-low voltage line VGL. When a voltage less than the second power voltage (that is, the common voltage ELVSS) of the gate-low voltage line VGL is applied to the data line DL due to electrostatic discharge, the third protective transistor TP3 and the fourth protective transistor TP4 may be turned on. In this case, a current may flow from the low voltage line VGL to the data line DL, and a voltage on the data line DL may increase. That is, the third protective transistor TP3 and the fourth protective transistor TP4 may increase a voltage that is less than the second power voltage.

A voltage on the data line DL may be maintained between the first power voltage and the second power voltage by the first to fourth protective transistors TP1, TP2, TP3, and TP4, allowing an inner circuit to be protected from electrostatic discharge.

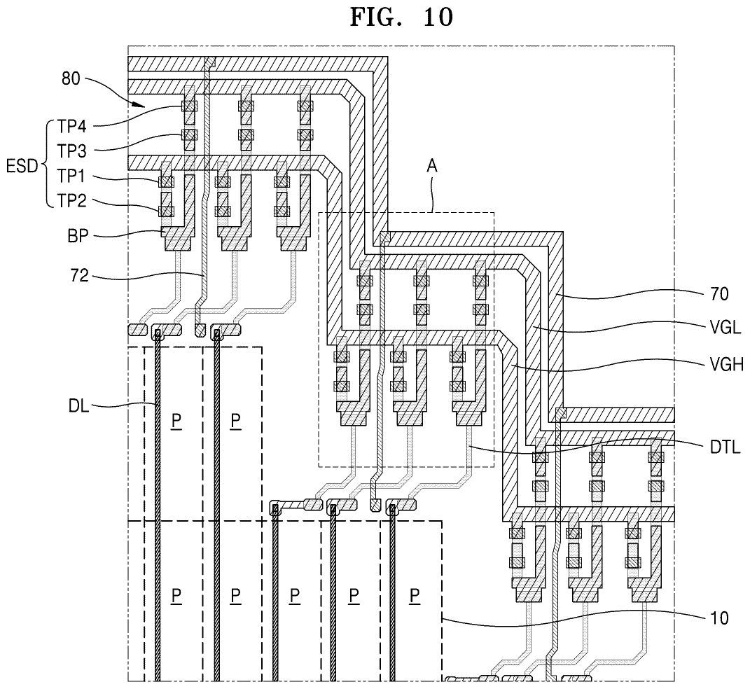

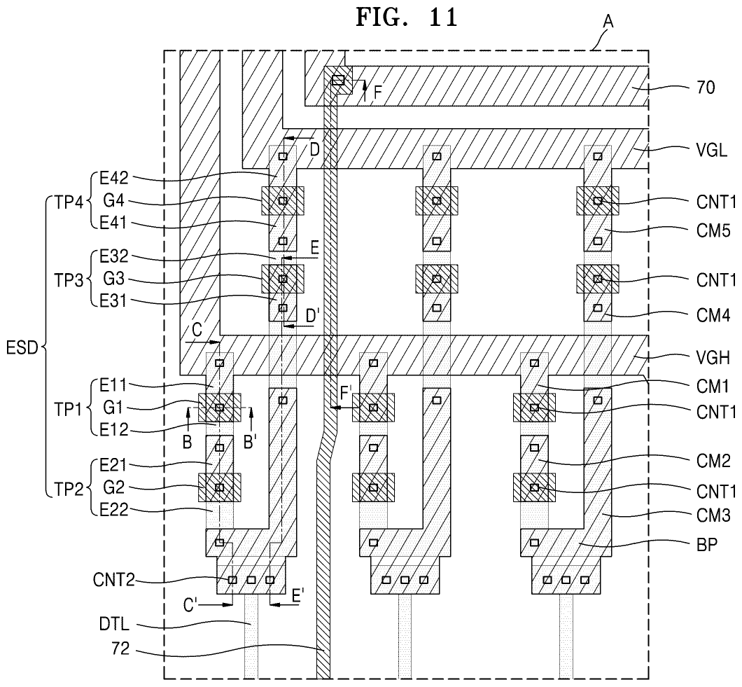

FIG. 10 is a schematic plan view of a portion of the non-display area of the display apparatus according to an embodiment, and FIG. 11 is a schematic plan view of a portion of the electrostatic discharge preventing part of the display apparatus according to an embodiment, corresponding to a region A of FIG. 10.

Referring to FIGS. 10 and 11, the electrostatic discharge preventing part 80 may be arranged in the non-display area NDA adjacent to the display area DA. The electrostatic discharge preventing part 80 may include at least one electrostatic discharge protective circuit ESD. In addition, the gate-high voltage line VGH (referred to as a first conductive line, hereinafter), the gate-low voltage line VGL (referred to as a second conductive line, hereinafter), and a common voltage supply line 70 may be arranged in the non-display area NDA adjacent to the display area DA.

The first conductive line VGH may be arranged in the non-display area NDA, which is outside the display unit 10. The first conductive line VGH may be arranged closest to the display unit 10 than the second conductive line VGL and the common voltage supply line 70. The first conductive line VGH may be apart by a preset interval from the display unit 10, and a portion (that is, the first and second protective transistors TP1 and TP2) of the electrostatic discharge protective circuit ESD and a signal transfer line DTL may be arranged between the first conductive line VGH and the display unit 10. As described above, the first conductive line VGH may correspond to the gate-high voltage line VGH of the electrostatic discharge protective circuit ESD of FIG. 9.

The second conductive line VGL may be arranged in the non-display area NDA. The second conductive line VGL may be arranged between the first conductive line VGH and the common voltage supply line 70. The second conductive line VGL may be apart by a preset interval from the first conductive line VGH, and a portion (that is, the third and fourth protective transistors TP3 and TP4) of the electrostatic discharge protective circuit ESD may be arranged between the second conductive line VGL and the first conductive line VGH. As described above, the second conductive line VGL may correspond to the gate-low voltage line VGL of the electrostatic discharge protective circuit ESD of FIG. 9.

The common voltage supply line 70 may be arranged in the non-display area NDA. Accordingly, the first conductive line VGH, the second conductive line VGL, and the common voltage supply line 70 may be arranged in an order close to the display unit 10. The common voltage supply line 70 may transfer the common voltage ELVSS to each pixel P through a voltage transfer line 72, as described below.

The electrostatic discharge preventing part 80 may be arranged between the display unit 10 and the second conductive line VGL. In addition, a first end of the electrostatic discharge preventing part 80 is electrically connected to the first conductive line VGH, and a second end of the electrostatic discharge preventing part 80 is electrically connected to the second conductive line VGL.

According to an embodiment, when the electrostatic discharge preventing part 80 is viewed in a plan view, a portion of the electrostatic discharge preventing part 80 may be arranged between the first conductive line VGH and the second conductive line VGL, and another portion of the electrostatic discharge preventing part 80 may be arranged between the first conductive line VGH and the display unit 10. More specifically, the electrostatic discharge preventing part 80 may include the first to fourth protective transistors TP1, TP2, TP3, and TP4. Among them, the first protective transistor TP1 and the second protective transistor TP2 may be arranged between the first conductive layer VGH and the display unit 10, and the third protective transistor TP3 and the fourth protective transistor TP4 may be arranged between the first conductive line VGH and the second conductive line VGL.

For this purpose, the electrostatic discharge preventing part 80 may be provided in a ‘U’ or ‘V’ shape, and provided to form at least one bending portion BP. Although the electrostatic discharge preventing part 80 shown in FIGS. 10 and 11 has an asymmetrically formed ‘U’ or ‘V’ shape, the present disclosure is not necessarily limited thereto.

In a plan view, the bending portion may be arranged between the display unit 10 and the first conductive line VGH, and may be arranged between the second protective transistor TP2 and the third protective transistor TP3. The bending portion BP may be a portion in which the electrostatic discharge preventing part 80 is connected to the signal transfer line DTL. The bending portion BP may be electrically connected to the signal transfer line DTL through a contact portion CNT2 (that is, a second contact hole). As described above, the signal transfer line DTL may correspond to the start signal line FLM.

The signal transfer line DTL may be electrically connected to the data line DL of each pixel P of the display unit 10. A first end of the signal transfer line DTL may be connected to the data line DL, and a second end of the signal transfer line DTL may be connected to a third contact metal CM3 of the electrostatic discharge preventing part 80. Accordingly, a data signal may be applied to the signal transfer line DTL. As described above, because the electrostatic discharge preventing part 80 has a ‘U’ or ‘V’ shape and the bending portion BP is arranged between the display unit 10 and the first conductive line VGH, the signal transfer line DTL may not overlap wirings arranged outside the display unit 10.

Specifically, in a plan view, the signal transfer line DTL may not overlap the first conductive line VGH and the second conductive line VGL. In addition, in a plan view, the signal transfer line DTL may not overlap the common voltage supply line 70. Since the electrostatic discharge preventing part 80 is provided in a ‘U’ or ‘V’ shape and the bending portion BP is arranged between the display unit 10 and the first conductive line VGH, the common voltage supply line 70 may be arranged in the outermost portion. As the signal transfer line DTL does not overlap with the common voltage supply line 70, the first conductive line VGH and the second conductive line VGL, peeling defects caused by electrostatic discharge that may occur in the overlapping region may be effectively prevented.

Hereinafter, structures of the electrostatic discharge protective circuit ESD included in the electrostatic discharge preventing part 80 is described in detail with reference to FIGS. 11 to 15.

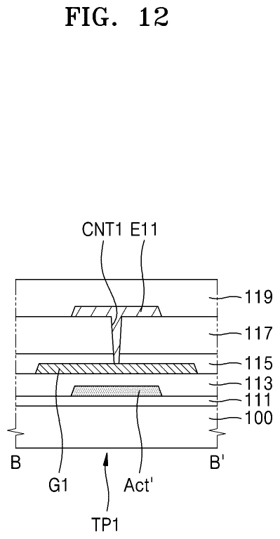

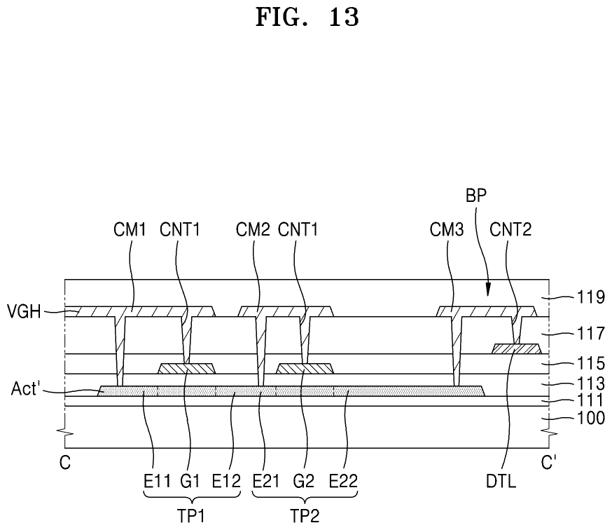

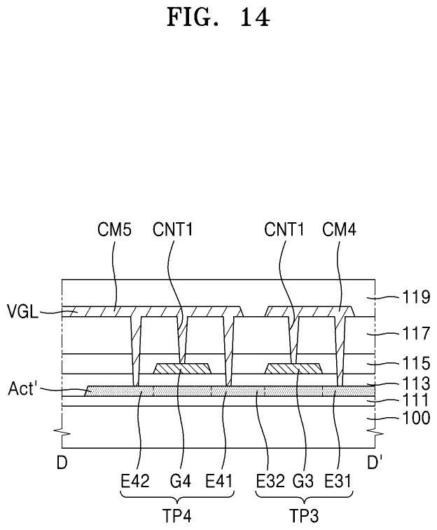

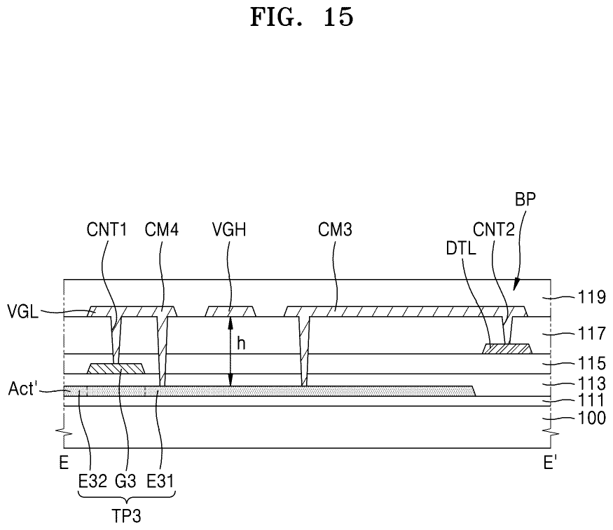

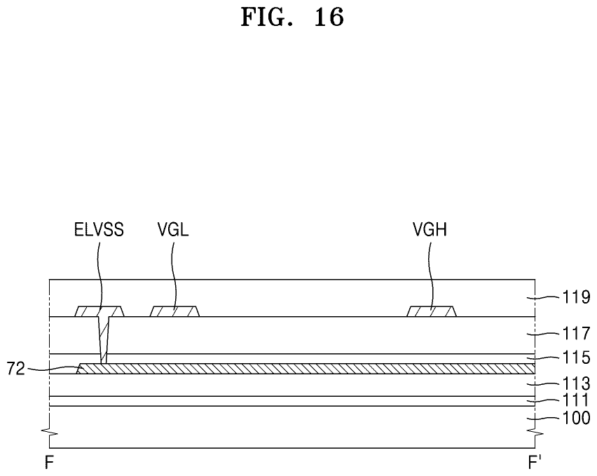

FIGS. 12 to 16 are schematic cross-sectional views of a portion of the electrostatic discharge preventing part of the display apparatus according to an embodiment. FIG. 12 is a schematic cross-sectional view of a portion of the electrostatic discharge preventing part, taken along a line B-B′ of FIG. 11, FIG. 13 is a schematic cross-sectional view taken along a line C-C′ of FIG. 11, FIG. 14 is a schematic cross-sectional view taken along a line D-D′ of FIG. 11, FIG. 15 is a cross-sectional view taken along a line E-E′ of FIG. 11, and FIG. 16 is a cross-sectional view taken along a line F-F′ of FIG. 11.

Referring to FIGS. 11 to 15, the electrostatic discharge preventing part 80 may include a plurality of electrostatic discharge protective circuits ESD. The electrostatic discharge protective circuit ESD may include the first protective transistor TP1, the second protective transistor TP2, the third protective transistor TP3, and the fourth protective transistor TP4. Each of the first protective transistor TP1, the second protective transistor TP2, the third protective transistor TP3, and the fourth protective transistor TP4 may include the gate electrode, the first electrode, and the second electrode.

Specifically, as shown in FIGS. 11 to 14, the first protective transistor TP1 may include a first gate electrode G1, a first electrode E11 and a second electrode E12, and the second protective transistor TP2 may include a second gate electrode G2, a first electrode E21 and a second electrode E22. The first electrode E11 of the first protective transistor TP1 may be connected to the first conductive line VGH corresponding to the gate-high voltage line VGH, and the second electrode E22 of the second protective transistor TP2 may be connected to the signal transfer line DTL corresponding to the start signal line FLM of FIG. 9.

In addition, as shown in FIGS. 11 to 14, the third protective transistor TP3 may include a third gate electrode G3, a first electrode E31 and a second electrode E32, and the fourth protective transistor TP4 may include a fourth gate electrode G4, a first electrode E41 and a second electrode E42. The first electrode E31 of the third protective transistor TP3 may be connected to the signal transfer line DTL corresponding to the start signal line FLM, and the second electrode E42 of the fourth protective transistor TP4 may be connected to the second conductive line VGL corresponding to the gate-low voltage line VGL of FIG. 9.

According to an embodiment, the first to fourth gate electrodes G1, G2, G3, and G4 of the first to fourth protective transistors TP1, TP2, TP3 and TP4 may be respectively connected to the first electrodes E11, E21, E31, and E41 of each of the first to fourth protective transistors TP1, TP2, TP3 and TP4 through the first contact holes CNT1.

Referring to FIGS. 12 to 16, the cross-sectional layered structure of the electrostatic discharge protective circuit ESD may have the same layered structure as the pixel P in the display unit 10 described with reference to FIG. 9. Hereinafter, the same layer such as the insulating layer extending from the display unit 10 is described using the same term.

An active layer Act′ may be disposed on the substrate 100, and the gate insulating layer 113 may be disposed on the active layer Act′. The first to fourth gate electrodes G1, G2, G3, and G4 may be disposed over the active layer Act′ with the gate insulating layer 113 therebetween. The first to fourth gate electrodes G1, G2, G3, and G4 may include a low-resistance metal material. Each of the first to fourth gate electrodes G1, G2, G3, and G4 may include a conductive material including molybdenum (Mo), aluminum (Al), copper (Cu) or titanium (Ti), and may have a single-layered structure or a multi-layered structure including the above materials.

The gate insulating layer 113 between the active layer Act′ and the first to fourth gate electrodes G1, G2, G3, and G4 may include an inorganic insulating material such as silicon oxide, silicon nitride, silicon oxynitride, aluminum oxide, titanium oxide, tantalum oxide, or hafnium oxide. The gate insulating layer 113 may be a single layer or a multi-layer including the above materials.

The first interlayer insulating layer 115 and the second interlayer insulating layer 117 may be disposed on the first to fourth gate electrodes G1, G2, G3, and G4, and first to fifth contact metals CM1, CM2, CM3, CM4, and CM5 may be disposed on the second interlayer insulating layer 117.

Specifically, the first electrode E11 of the first protective transistor TP1 may be electrically connected to the first gate electrode G1 through the first contact metal CM1. The first contact metal CM1 may be a portion of the first conductive line VGH extending in the first direction (e.g., the -y direction). The second electrode E12 of the first protective transistor TP1 and the first electrode E21 of the second protective transistor TP2 may be electrically connected to the second gate electrode G2 of the second protective transistor TP2 through the second contact metal CM2. The second electrode E22 of the second protective transistor TP2 may be electrically connected to the signal transfer line DTL through the third contact metal CM3. In addition, the second electrode E32 of the third protective transistor TP3 may be electrically connected to the signal transfer line DTL through the third contact metal CM3. The second electrode E32 of the third protective transistor TP3 may be electrically connected to the third gate electrode G3 through the fourth contact metal CM4. The fifth contact metal CM5 may electrically connect the second conductive line VGL to the fourth protective transistor TP4. The fifth contact metal CM5 may be a portion of the second conductive line VGL extending in the first direction (e.g., the -y direction).

Referring to FIGS. 11 to 15, the electrostatic discharge protective circuit ESD may include the active layer Act′. According to an embodiment, as the electrostatic discharge protective circuit ESD has a ‘U’ or ‘V’ shape, the active layer Act′ may have the same as or the similar shape to the electrostatic discharge protective circuit ESD.

The active layer Act′ may have a doped portion in a region not overlapping with the gate electrodes (e.g., the first to fourth gate electrodes G1, G2, G3, and G4). As depicted in FIG. 15, a portion of the doped active layer Act′ may be disposed to overlap the first conductive line VGH. When connecting the gate electrode (that is, the third gate electrode G3) to the signal transfer line DTL, it is inevitable to include an overlapping region with the first conductive line VGH. By utilizing the doped active layer Act′, which is a closest layer to the substrate 100, a separation distance h, in a vertical direction (e.g., a z axis direction), between the doped active layer Act′ and the first conductive line VGH may be increased, thereby reducing issues such as short circuits or parasitic capacitors between the wirings.

Referring to FIGS. 11 to 16, the display apparatuses 1 and 1′ according to an embodiment may further include the voltage transfer line 72 electrically connecting the display unit 10 to the common voltage supply line 70. That is, one end of the voltage transfer line 72 is connected to the common voltage supply line 70, and the other end of the voltage transfer line 72 is connected to the display unit 10, so that the voltage transfer line 72 may transfer a common voltage to each pixel P located in the display unit 10. Because the common voltage supply line 70 is arranged in the outermost portion compared to the first conductive line VGH and the second conductive line VGL, the voltage transfer line 72 electrically connecting the common voltage supply line 70 to the display unit 10 is required. Although it is shown that the voltage transfer line 72 extends in the first direction (e.g., the y axis direction), the present disclosure is not necessarily limited thereto.

Because the voltage transfer line 72 extends in the first direction (e.g., the y axis direction) and is connected to the common voltage supply line 70, at least a portion of the voltage transfer line 72 may overlap the first conductive line VGH and the second conductive line VGL. In addition, at least a portion of the voltage transfer line 72 may overlap the signal transfer line DTL. In this case, the voltage transfer line 72 and the signal transfer line DTL may be disposed on different layers from each other. For example, the voltage transfer line 72 may be disposed on the same layer as the gate electrode GE, and the signal transfer line DTL may be disposed on the same layer as the second electrode CE2 of the storage capacitor Cst.

Although descriptions about an embodiment of the present disclosure have mainly focused on, the present disclosure is not limited thereto. For example, a method of manufacturing a display apparatus having the electrostatic discharge protective circuit ESD also falls within the scope of the present disclosure.

A display apparatus of the present disclosure may minimize a circuit damage due to electrostatic discharge. However, the scope of the present disclosure is not limited by this effect.

It should be understood that embodiments described herein should be considered in a descriptive sense only and not for purposes of limitation. Descriptions of features or aspects within each embodiment should typically be considered as available for other similar features or aspects in other embodiments. While the present disclosure has been described with reference to the drawings, it will be understood by those of ordinary skill in the art that various changes in form and details may be made thereto without departing from the spirit and scope of the present disclosure as set forth and defined by the following claims.

What is claimed is:

1. A display apparatus including a display area and a non-display area, comprising:
a display unit disposed in the display area, and including a light-emitting element and a pixel circuit electrically connected to the light-emitting element;
a common voltage supply line arranged in the non-display area surrounding the display area;
a first conductive line arranged between the display unit and the common voltage supply line;
a second conductive line arranged between the first conductive line and the common voltage supply line;
an electrostatic discharge protective circuit having a first end connected to the first conductive line and a second end connected to the second conductive line, and including a first protective transistor arranged between the display unit and the first conductive line and a second protective transistor arranged between the first conductive line and the second conductive line; and
a signal transfer line including a contact portion in contact with the electrostatic discharge protective circuit to transfer signals between the first protective transistor and the second protective transistor,
wherein the contact portion is disposed between the display unit and the first conductive line.

2. The display apparatus of claim 1, wherein the signal transfer line is arranged between the display unit and the first conductive line.

3. The display apparatus of claim 1, wherein the signal transfer line is spaced apart from the second conductive line along a first direction.

4. The display apparatus of claim 1, wherein the signal transfer line is arranged closest to the display unit, and the common voltage line is arranged farthest to the display unit.

5. The display apparatus of claim 1, wherein the electrostatic discharge protective circuit has a bent portion between the first protective transistor and the second protective transistor.

6. The display apparatus of claim 5, wherein the bent portion is placed between the display unit and the first conductive line.

7. The display apparatus of claim 5, wherein the contact portion of the signal transfer line is connected to the bent portion.

8. The display apparatus of claim 5, wherein the electrostatic discharge protective circuit has a ‘V’ or ‘U’ shape.

9. The display apparatus of claim 1, wherein a data signal is applied to the signal transfer line.

10. The display apparatus of claim 9, wherein the display unit further includes a data line extending in a first direction, and a first end of the signal transfer line is electrically connected to the data line.

11. The display apparatus of claim 1, wherein the electrostatic discharge protective circuit includes a doped active layer, and the doped active layer overlaps the first conductive line.

12. The display apparatus of claim 1, further comprising a voltage transfer line electrically connecting the display unit to the common voltage supply line.

13. The display apparatus of claim 12, wherein at least a portion of the voltage transfer line overlaps the first conductive line.

14. The display apparatus of claim 12, wherein at least a portion of the voltage transfer line overlaps the second conductive line.

15. The display apparatus of claim 12, wherein the signal transfer line and the voltage transfer line are disposed on different layers from each other.

16. The display apparatus of claim 12, wherein the signal transfer line is disposed on a higher layer than the voltage transfer line.

17. The display apparatus of claim 12, wherein the pixel circuit includes a semiconductor layer, a gate electrode overlapping at least a portion of the semiconductor layer, a storage electrode on the gate electrode, a first electrode layer on the storage electrode, and a second electrode layer on the first electrode layer,
wherein the signal transfer line is disposed on a same layer as the storage electrode, and the voltage transfer line is disposed on a same layer as the gate electrode.

18. The display apparatus of claim 1, wherein at least a portion of the display area includes at least one rounded corner at an outer portion of the display unit.

19. The display apparatus of claim 1, wherein at least a portion of the display area includes a polygonal shape.

20. The display apparatus of claim 1, wherein the light-emitting element is arranged in a diagonal or stepped shape in at least a portion of an outer portion of the display unit.

21. The display apparatus of claim 1, wherein the display apparatus is part of one of a mobile phone, a tablet, a mobile communication terminal, an electronic notebook, an e-book, a portable multimedia player, a navigation device, an ultra-mobile personal computer, a television, a monitor, a billboard, an Internet of Things device, a smart watch, a watch phone, glasses, a head mounted display, a vehicle dashboard, a vehicle mirror display, or a vehicle entertainment display.
